(19) United States
(12) Patent Application Publication
(10) Pub. No.: US 2008/0011454 A1
(43) Pub. Date: Jan. 17, 2008

(54) HEAT DISSIPATION APPARATUS

(76) Inventors: CHING-BAI HWANG, Tu-Cheng (TW); JIN-GONG MENG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(21) Appl. No.: 11/615,906

(22) Filed: Dec. 22, 2006

(30) Foreign Application Priority Data
Jul. 12, 2006 (CN) 200610061620.1

(51) Int. Cl. H05K 7/20

(52) U.S. Cl. 165/80.3; 165/122; 165/104.33; 361/697; 361/700

(57) ABSTRACT

A heat dissipation apparatus (10) includes a centrifugal blower (14) defining an air outlet (148) therein; and a fin assembly (12) is disposed at the air outlet of the centrifugal blower. The fin assembly includes an arc portion (121) and a rectangular portion (122) extending from an end of the arc portion. The arc portion includes a plurality of first fins (123), whilst the rectangular portion includes a plurality of second fins (124). The first fins form a plurality of sector-shaped passages (131) therebetween, whilst the second fins form a plurality of rectangular-shaped passages (132) therebetween.

### BACKGROUND OF THE INVENTION

1. Field of the Invention

The present invention relates generally to a heat dissipation apparatus, and more particularly to a heat dissipation apparatus for dissipating heat generated by electronic components.

2. Description of Related Art

Following the increase in computer processing power that has been seen in recent years, greater emphasis is now being laid on increasing the efficiency and effectiveness of heat dissipation devices. Referring to FIG. 6, a heat dissipation apparatus 20 in accordance with related art includes a centrifugal blower 22 and a fin assembly 24 disposed at an air outlet 211 of the centrifugal blower 22. The fin assembly 24 includes a plurality of fins 242 which thermally connect with a heat generating electronic component (not shown) to absorb heat therefrom. The centrifugal blower 22 includes a casing 222, a stator (not shown) mounted in the casing 222, and a rotor 223 rotatably disposed around the stator. When the centrifugal blower 22 is activated, the rotor 223 rotates in a counterclockwise direction around the stator, creating an airflow flowing through the fin assembly 24 in a manner so as to take away heat therefrom.

In operation of the heat dissipation apparatus 20, the casing 222 guides the airflow to move towards an upper side 246 of the air outlet 211 of the centrifugal blower 22. A portion of the airflow leaves the centrifugal blower 22 at the upper side 246 of the air outlet 211 with another portion flowing towards a bottom side 244 of the fin assembly 24 from the upper side 246 thereof. A flow direction of the airflow flowing toward the upper side 246 of the fin assembly 24 is substantially parallel to the fins 242 thereof, while the airflow flowing toward the bottom side 244 of the fin assembly 24 forms an acute angle with each fin 242 of the bottom side 244 of the fin assembly 24. The airflow flowing toward the bottom side 244 of the fin assembly 24 may be deflected by the fins 242 thereof due to the acute angles formed therebetween. This deflection of the airflow may cause a loss in kinetic energy of the airflow. Thus speed of the airflow flowing toward the bottom side 244 of the fin assembly 24 may be reduced. The heat dissipation efficiency of the heat dissipation apparatus 20 will thereby be further reduced. Accordingly, it can be seen that the heat dissipation efficiency of the heat dissipation apparatus 20 has room for improvement.

### SUMMARY OF THE INVENTION

The present invention relates to a heat dissipation apparatus for dissipating heat generated by an electronic component. According to a preferred embodiment of the present invention, the heat dissipation apparatus includes a centrifugal blower defining an air outlet therein; and a fin assembly is disposed at the air outlet of the centrifugal blower. The fin assembly includes an arc portion and a rectangular portion. The arc portion includes a plurality of first fins, whilst the rectangular portion includes a plurality of second fins. The first fins form a plurality of sector-shaped passages therebetween, whilst the second fins form a plurality of rectangular-shaped passages therebetween.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a heat dissipation apparatus according to a preferred embodiment of the present invention;

FIG. 2 is an assembled view of the heat dissipation apparatus of FIG. 1;

FIG. 3 is an isometric view of a first fin of a fin assembly of FIG. 1;

FIG. 4 is an isometric view of a second fin of the fin assembly of FIG. 1;

FIG. 5 is a top view of the heat dissipation apparatus with some parts thereof removed, which shows flow directions of an airflow generated by a centrifugal blower of the heat dissipation apparatus;

FIG. 6 is an isometric view of a fin assembly of a heat dissipation apparatus according to a second embodiment of the present invention; and

FIG. 7 is a top view of a heat dissipation apparatus in accordance with related art, with some parts thereof removed, which shows flow directions of an airflow generated by a centrifugal blower of the related heat dissipation apparatus.

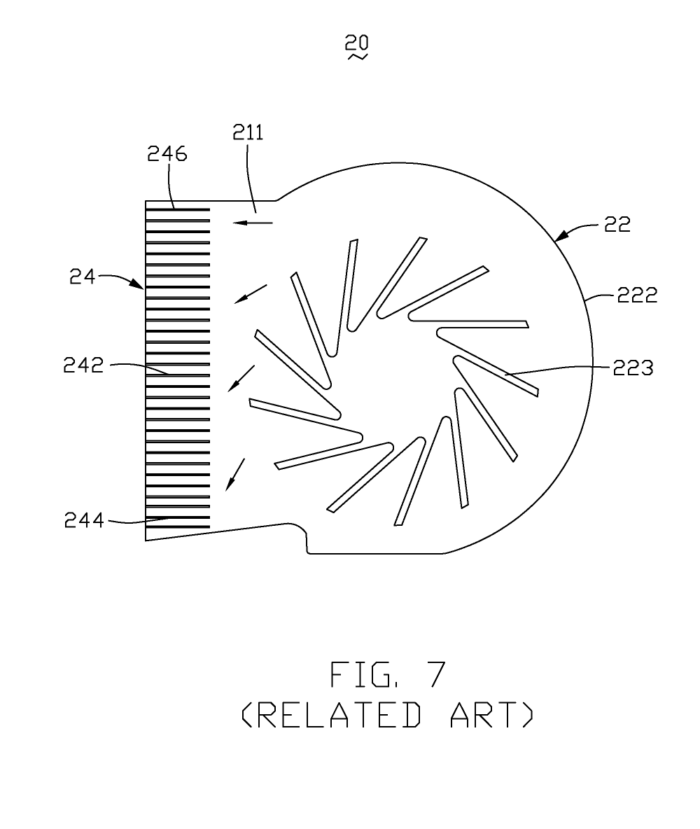

### DETAILED DESCRIPTION OF THE INVENTION

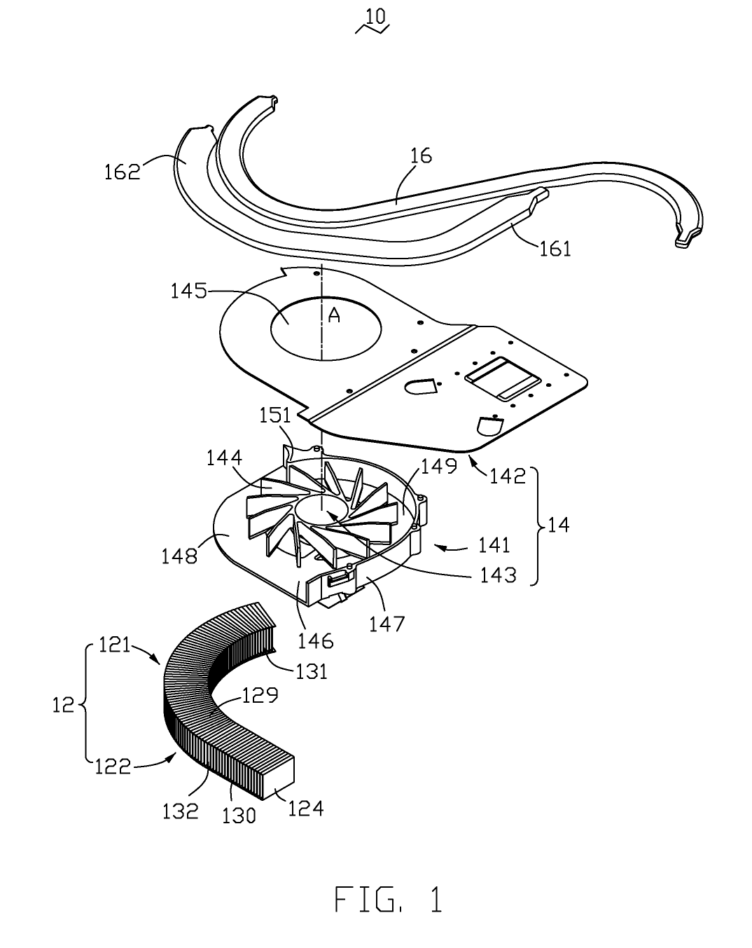

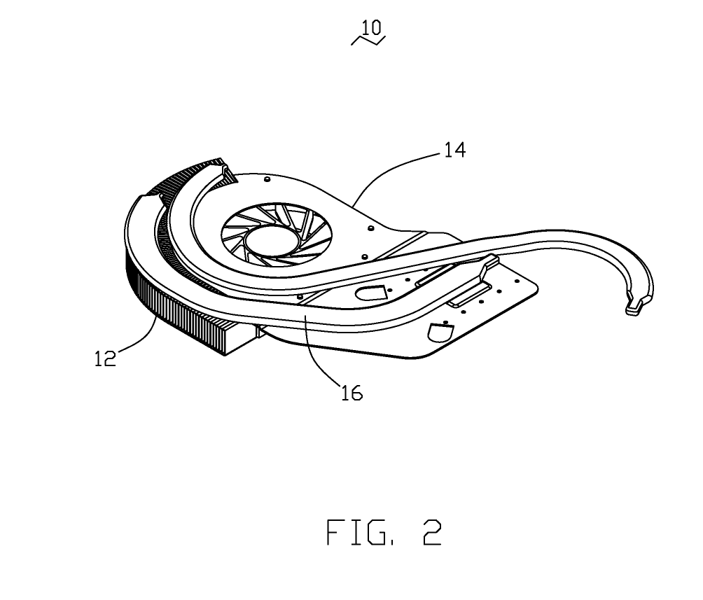

Referring to FIGS. 1 to 3, a heat dissipation apparatus 10 according to a preferred embodiment of the present invention is shown. The heat dissipation apparatus 10 includes a fin assembly 12 thermally connected with two heat-generating electronic components (not shown) to absorb heat therefrom, and a centrifugal blower 14 for providing an airflow flowing through the fin assembly 12 to take the heat away. The fin assembly 12 thermally connects with the heat-generating electronic components via two flattened heat pipes 16. Each of the heat pipes 16 includes an evaporator section 161 contacting with the corresponding heat-generating electronic component and a condenser section 162 contacting with the fin assembly 12.

The centrifugal blower 14 includes a bottom housing 141, a top cover 142 covering on the bottom housing 141, a stator (not shown) mounted in a space formed between the bottom housing 141 and the top cover 142, and a rotor 143 including a plurality of blades 144 rotatably disposed around the stator.

The top cover 142 is a planar plate, which defines an air inlet 145 therein. The bottom housing 141 includes a flattened base plate 146 perpendicular to a rotation axis A of the rotor 143, and an arc-shaped sidewall 147 perpendicular to the top cover 142 and the base plate 146 of the bottom housing 141. The heat-generating electronic components are disposed at one side of the fin assembly 12 along a direction parallel to the top cover 142 of the centrifugal blower 14. The bottom housing 141 defines an arc-shaped air outlet 148 therein, facing the sidewall 147. The sidewall 147 projects a triangular tongue 151 at a left side of the air outlet 148. The tongue 151 extends from the sidewall 147 towards the rotor 143 so that the tongue 151 spaces a nearer distance from the rotor 143 than other portions of the sidewall 147. The air pressure of the airflow flowing through the tongue 151 is therefore increased, which accordingly increases the flow speed of the airflow flowing through the fin assembly 12. An air channel 149 is formed between free ends of the rotor 143 and an inner surface of the sidewall 147. A width of the air channel 149 is gradually increased from the tongue 151 towards an opposite right side of the air outlet 148.

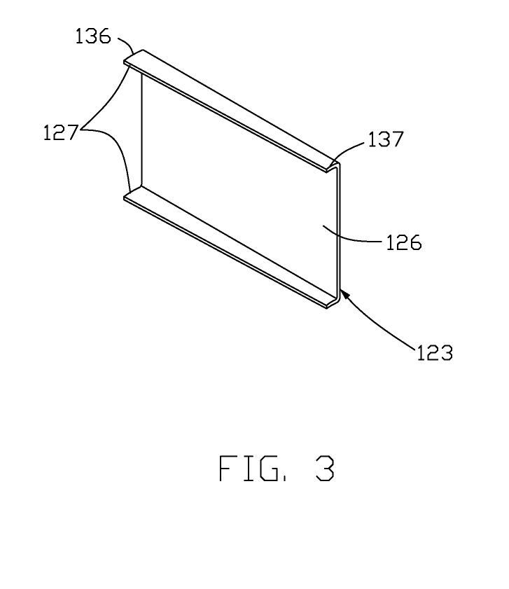

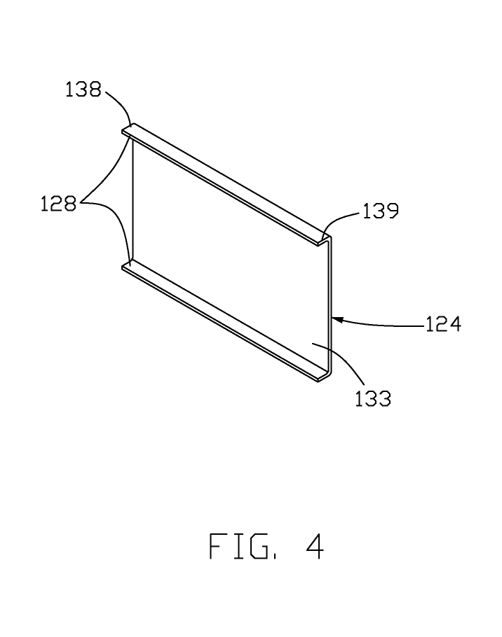

The fin assembly 12 is arranged at the air outlet 148 of the centrifugal blower 14 and is substantially arc-shaped in profile so as to match the air outlet 148. The fin assembly 12 includes a top surface 129 and a bottom surface 130. The top surface 129 of the fin assembly 12 contacts with the condenser sections 162 of the heat pipes 16. The condenser sections 162 of the heat pipes 16 are arc-shaped in profile so as to match the fin assembly 12. The bottom surface 130 of the fin assembly 12 is coplanar with a bottom surface of the base plate 146 of the bottom housing 141. The fin assembly 12 includes an arc portion 121 disposed adjacent to the tongue 151 of the centrifugal blower 14, and a rectangular (linear) portion 122 extending along a tangent direction of one end of the arc portion 121. The arc portion 121 includes a plurality of stacked first fins 123, whilst the rectangular portion 122 includes a plurality of stacked second fins 124. Particularly referring to FIG. 3, each of the first fins 123 includes a rectangular shaped main body 126 and two flanges 127 perpendicularly extending from top and bottom ends of the main body 126. Each of the flanges 127 includes a first end 136 and a second end 137 opposite to the first end 136 and adjacent to the free ends of the rotor 143. A width of the flange 127 is gradually increased from the second end 137 towards the first end 136, so that the flange 127 is substantially sector-shaped in profile. Particularly referring to FIG. 4, each of the second fins 124 includes a rectangular shaped main body 133 and two flanges 128 perpendicularly extending from top and bottom ends of the main body 133. Each of the flanges 128 includes a first end 138 and a second end 139 opposite to the first end 138 and adjacent to the free ends of the rotor 143. A width of the second end 139 of the flange 128 is substantially equal to a width of the first end 138 of the flange 128, so that the flange 128 is substantially rectangular-shaped in profile. The flanges 128 of a rear first fin 123 and the flanges 128 of a rear second fin 124 respectively abut against the main body 126 of a front first fin 123 and the main body 133 of a front second fin 124 so as to keep a distance therebetween. A sector-shaped first passage 131 is formed between two adjacent first fins 123, whilst a rectangular-shaped second passage 132 is formed between two adjacent second fins 124.

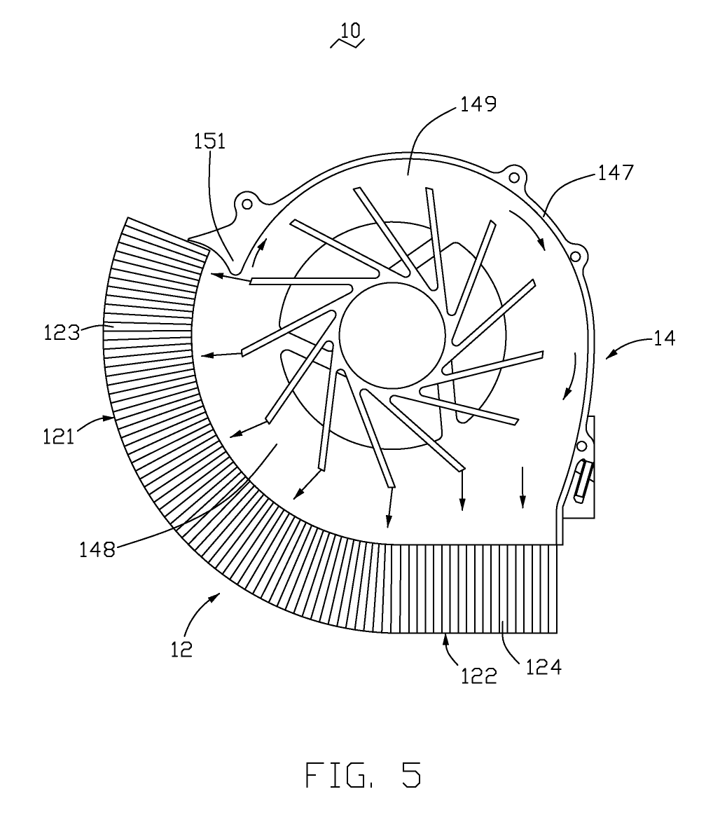

Referring to FIG. 5, in operation of the centrifugal blower 14, the airflow generated by the rotation of the blades 144 flows through the tongue 151 with its pressure being increased. The sidewall 147 guides the airflow to flow towards the right side of the air outlet 148. When the airflow leaves the air outlet 148, it flows from the right side of the air outlet 148 towards the left side of thereof. One part of the airflow enters into the rectangular portion 122 of the fin assembly 12 along a direction substantially parallel to the second passages 132 between the second fins 124. The other part of the airflow enters into the arc portion 121 of the fin assembly 12 along a direction substantially parallel to the first passages 131 between the first fins 123.

In the present heat dissipation apparatus 10, the fin assembly 12 consists of the arc portion 121 and the rectangular portion 122. Each of the main bodies 126 of the first fins 123 of the arc portion 121 and each of the main bodies 133 of the second fins 124 of the rectangular portion 122 is arranged to a direction which substantially parallels to the flow direction of the airflow flowing therethrough. This makes the airflow flow evenly through the first and second passages 131, 132 of the fin assembly 12. So the airflow arriving at the fin assembly 12 will not be fiercely deflected by the first and second fins 123, 124 of the fin assembly 12. The kinetic energy loss from the airflow is thus prevented and the heat dissipation efficiency of the heat dissipation apparatus 10 is thereby increased.

Moreover, a cross-sectional area of each of the second passages 132 of the fin assembly 12 is gradually increased from inner side of the fin assembly 12 towards outer side thereof, which decreases the flow resistance of the airflow. Therefore, the airflow can smoothly flow through the second passages 132, which further improves the heat dissipation efficiency of the heat dissipation apparatus 10. In addition, the configuration of the arc portion 121 of the fin assembly 12 matches the configurations of the condenser sections 162 of the heat pipes 16, which increases the thermal contact area therebetween and thereby increasing the heat dissipation efficiency of the heat dissipation apparatus 10.

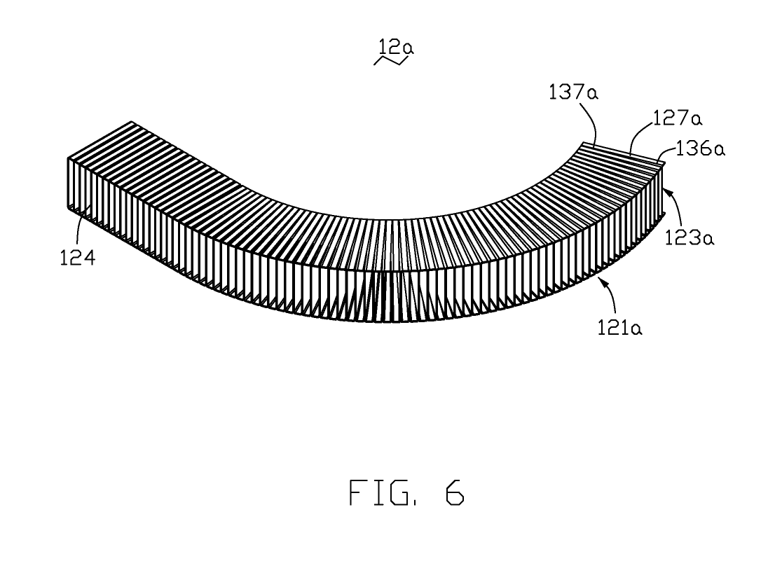

Referring to FIG. 6, a fin assembly 12a of the heat dissipation apparatus 10 in accordance with a second embodiment of the present invention is shown. In this embodiment, a width of the first end 136a of the flange 127a of the first fin 123a is equal to a width of the second end 137a thereof. The second ends 137a of adjacent first fins 123 are bonded together, with the first ends 136a of the adjacent first fins 123 spacing a distance from each other so as to form the arc portion 121a of the fin assembly 12a and the sector-shaped first passages 131 therebetween. In this embodiment, there is no need to design an extra die for forming the first fins 123a. The fin assembly 12a is made just by one kind of die, which decreases the cost of the fin assembly 12a. In other words, in this embodiment, the first fin 123a has a configuration and size the same as those of the second fin 124.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus comprising:
a centrifugal blower defining an air outlet therein;
a fin assembly disposed at the air outlet of the centrifugal blower, and comprising an arc portion comprising a plurality of first fins, wherein a sector-shaped passage is formed between two adjacent first fins; and
at least a heat pipe configured for thermally connecting the fin assembly with a heat generating electronic component.

2. The heat dissipation apparatus as described in claim 1, wherein each of the first fins comprises a main body and two flanges extending from two opposite ends of the main body, the flanges of each of the first fins being sector-shaped in profile.

3. The heat dissipation apparatus as described in claim 1, wherein each of the first fins comprises a main body and two flanges extending from two opposite ends of the main body, the flanges of each of the first fins being rectangular-shaped in profile and comprising first ends and second ends opposite to the first ends and adjacent to a rotor of the centrifugal blower, the second ends of two adjacent first fins contacting with each other and the first ends of the two adjacent first fins spacing a distance from each other.

4. The heat dissipation apparatus as described in claim 1, wherein the main bodies of the first fins respectively and substantially parallel to the flow direction of the airflow flowing therethrough.

5. The heat dissipation apparatus as described in claim 1, wherein the fin assembly further comprises a rectangular portion comprising a plurality of second fins, a rectangular-shaped passage being formed between two adjacent second fins.

6. The heat dissipation apparatus as described in claim 5, wherein each of the second fins comprises a main body and two flanges extending from two opposite ends of the main body, the flanges of each of the second fins being rectangular-shaped in profile.

7. The heat dissipation apparatus as described in claim 1, wherein the heat pipe comprises an arc-shaped condenser section matching the arc portion of the fin assembly and thermally connecting therewith.

8. The heat dissipation apparatus as described in claim 1, wherein the centrifugal blower comprises a sidewall and a rotor, the sidewall extending a tongue at one side of the air outlet, the tongue spacing a nearer distance from the rotor than other portions of the sidewall.

9. The heat dissipation apparatus as described in claim 8, wherein the arc portion of the fin assembly is disposed adjacent to the tongue of the centrifugal blower.

10. A heat dissipation apparatus comprising:
a centrifugal blower defining an air outlet therein; and
a fin assembly disposed at the air outlet of the centrifugal blower, and comprising an arc portion and a rectangular portion, the arc portion comprising a plurality of first fins, the rectangular portion comprising a plurality of second fins, the first fins forming a plurality of sector-shaped passages therebetween, the second fins forming a plurality of rectangular-shaped passages therebetween.

11. The heat dissipation apparatus as described in claim 10, wherein the rectangular portion extends along a tangent direction of one end of the arc portion.

12. The heat dissipation apparatus as described in claim 10, wherein each of the first fins comprises a main body and two flanges extending from two opposite ends of the main body, the flanges of each of the first fins being sector-shaped in profile.

13. The heat dissipation apparatus as described in claim 10, wherein each of the first fins comprises a main body and two flanges extending from two opposite ends of the main body, the flanges of each of the first fins being rectangular-shaped in profile and comprising first ends and second ends opposite to the first ends and adjacent to a rotor of the centrifugal blower, the second ends of two adjacent first fins contacting with each other and the first ends of the two adjacent first fins spacing a distance from each other.

14. The heat dissipation apparatus as described in claim 10, wherein the airflow generated by the centrifugal blower firstly flows towards the rectangular portion and then to the arc portion of the fin assembly.
